(19) United States
(12) Patent Application Publication
(10) Pub. No.: US 2010/0173470 A1
(43) Pub. Date: Jul. 8, 2010

(54) Methods of forming a silicon oxide layer and methods of forming an isolation layer

(75) Inventors: Mong-Sup Lee, Seongnam-si (KR); In-Seak Hwang, Suwon-si (KR); Keum-Joo Lee, Hwaseong-si (KR); Jin-Hye Bae, Suwon-si (KR); Bo-Wo Choi, Seoul (KR); Seung-Jae Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,933

(22) Filed: Jan. 8, 2010

(30) Foreign Application Priority Data
Jan. 8, 2009 (KR) 10-2009-0001529

(51) Int. Cl. H01L 21/762; H01L 21/3105

(52) U.S. Cl. 438/427; 438/781; 257/E21.242; 257/E21.548

(57) ABSTRACT

In a method of forming a silicon oxide layer, a spin-on-glass (SOG) layer may be formed on an object including a recess using an SOG composition. The SOG layer may be pre-baked and then cured by contacting with at least one material selected from the group consisting of water, a basic material and an oxidant, under a pressure of from about 1.5 atm to about 100 atm. The cured SOG layer may be baked.

### CLAIM OF PRIORITY

This application claims priority under 35 U.S.C. §119 to Korean Patent Application No. 2009-0001529, filed on Jan. 8, 2009, in the Korean Intellectual Property Office (KIPO), the contents of which are herein incorporated by reference in their entirety.

### BACKGROUND

1. Field

Example embodiments of inventive concepts relate to methods of forming a silicon oxide layer and methods of forming an isolation layer using the same. More particularly, example embodiments of inventive concepts relate to methods of forming a silicon oxide layer having increased alignment characteristics and methods of forming an isolation layer using the same.

2. Description of the Related Art

Semiconductor devices are required to have a rapid response time and/or a large storage capacity. In response to the requirements; the semiconductor devices have been developed with increased integration degree, reliability, response time, etc. As the integration degree increases, the design rule of the semiconductor devices decreases.

A spin-on-glass (SOG) composition including perhydropolysilazane has good gap-fill characteristics and has been widely used for forming an isolation layer or an insulating interlayer. When an SOG layer including perhydropolysilazane is formed to fill a trench or an opening, a baking process may be performed at a high temperature so that the SOG layer is transformed into a silicon oxide layer.

The SOG layer rapidly shrinks during the baking process at the high temperature, thereby generating a crack or a void in the resultant silicon oxide layer. When a plurality of trenches or a plurality of openings having different widths are filled with the SOG layer, the shrinkage degree of the SOG layer at each trench or opening may be different, so that a substrate having the trenches or the openings is damaged and that misalignment of the silicon oxide layers on the trench or the opening occurs.

### SUMMARY

Example embodiments of inventive concepts relate to methods of forming a silicon oxide layer and methods of forming an isolation layer using the same.

Example embodiments of inventive concepts provide a method of forming a silicon oxide layer having increased alignment characteristics.

Example embodiments of inventive concepts provide a method of forming an isolation layer using a method of forming a silicon oxide layer having increased alignment characteristics.

According to example embodiments of inventive concepts, a method of forming a silicon oxide layer includes forming a spin-on-glass (SOG) layer using an SOG composition on an object, pre-baking the SOG layer, curing the SOG layer by contacting the pre-baked SOG layer with at least one selected from the group consisting of water, a basic material and an oxidant, under a pressure of about 1.5 atm to about 100 atm, and baking the cured SOG layer.

In example embodiments of inventive concepts, the curing of the pre-baked SOG layer may be performed in an autoclave.

In example embodiments of inventive concepts, the basic material may include at least one selected from the group consisting of ammonia (NH₃), ammonium hydroxide (NH₄OH), tetra methyl ammonium hydroxide (N(CH₃)₄OH), sodium hydroxide (NaOH), magnesium hydroxide (Mg(OH)₂), calcium hydroxide (Ca(OH)₂), potassium hydroxide (KOH) and combinations thereof.

In example embodiments of inventive concepts, the oxidant may include at least one selected from the group consisting of oxygen (O₂), ozone (O₃), nitrous acid (HNO₂), perchloric acid (HClO₄), chloric acid (HClO₃), chlorous acid (HClO₂), hypochlorous acid (HClO), hydrogen peroxide (H₂O₂) sulfuric acid (H₂SO₄) and combinations thereof.

In example embodiments of inventive concepts, the SOG composition may include about 5% to about 25% by weight of perhydropolysilazane and a remaining amount of solvent. The perhydropolysilazane may have a weight average molecular weight of about 2,000 to about 4,500 and a number average molecular weight of about 500 to about 2,000. The solvent may include at least one selected from the group consisting of toluene, benzene, xylene, dibutylether, diethyl ether, tetrahydrofuran (THF), propylene glycol methyl ether (PGME), propylene glycol methyl ether acetate (PGMEA), hexane and combinations thereof.

In example embodiments of inventive concepts, the object may include a trench thereon and the SOG layer is formed to fill the trench. The object may include a first trench having a first width and a second trench having a second width different from the first width.

In example embodiments of inventive concepts, the pre-baked SOG layer may be cured by immersing the SOG layer into water, a liquid of the basic material, a liquid of the oxidant or a liquid of a combination thereof. The pre-baked SOG layer may be cured by spraying the water or the liquid onto the SOG layer.

In example embodiments of inventive concepts, the pre-baked SOG layer may be cured by contacting the SOG layer with water vapor or a gas including the basic material, the oxidant or a combination thereof.

In example embodiments of inventive concepts, the pre-baked SOG layer may be cured by contacting the SOG layer with an aqueous solution of the basic material or an aqueous solution of the oxidant.

In example embodiments of inventive concepts, the pre-baked SOG layer may be cured at a temperature of about 50° C. to about 150° C. The pre-baked SOG layer may be cured for about 5 seconds to about 30 minutes.

In example embodiments of inventive concepts, the pre-baked SOG layer may be cured at a temperature of about 70° C. to about 130° C. under a pressure of from about 2 atm to about 15 atm.

In example embodiments of inventive concepts, the pre-baking of the SOG layer may include first pre-baking the SOG layer at a temperature of about 70° C. to about 150° C. and secondly pre-baking of the SOG layer at a temperature of about 200° C. to about 350° C. According to example embodiments of inventive concepts, the first and second pre-baking processes may be continuous. According to other example embodiments of inventive concepts, the first pre-baking process may be separate from the second pre-baking process.

In example embodiments of inventive concepts, the cured SOG layer may be baked at a temperature of about 400° C. to about 1,000° C.

According to example embodiments of inventive concepts, a method of forming an isolation layer includes forming a first trench and a second trench on a substrate. The first trench may have a first width and a first depth and the second trench may have a second width and a second depth. An SOG layer may be formed on the substrate to fill the first trench and the second trench. The SOG layer may be pre-baked. The pre-baked SOG layer may be cured by contacting the pre-baked SOG layer with at least one selected from the group consisting of water, a basic material and an oxidant, under a pressure of from about 1.5 atm to about 100 atm. The cured SOG layer may be baked, transforming the cured SOG layer into a silicon oxide layer. The silicon oxide layer may serve as the isolation layer.

In example embodiments of inventive concepts, the substrate may include a cell region and a peripheral region. The first trench may be formed in the cell region and the second trench may be formed in the peripheral region.

In example embodiments of inventive concepts, the first width and the second width may be different from each other.

According to example embodiments of inventive concepts of the method of forming a silicon oxide layer, an SOG layer may contact at least one of water, a basic material and an oxidant, and then may be cured under a substantially high pressure prior to performing a baking process at a substantially high temperature. During transformation of the SOG layer into the silicon oxide layer, a rapid shrinkage of the SOG layer may be prevented, thereby to preventing (or reducing the likelihood of) damage to a substrate and to form the silicon oxide layer on a desired position.

### BRIEF DESCRIPTION OF THE DRAWINGS

Example embodiments of inventive concepts will be more clearly understood from the following detailed description taken in conjunction with the accompanying drawings. FIGS. 1 to 14 represent non-limiting, example embodiments of inventive concepts as described herein.

FIG. 1 is a flow-chart illustrating a method of forming a silicon oxide layer pattern in accordance with example embodiments of inventive concepts.

FIGS. 2 to 7 are cross-sectional views illustrating a method of forming an isolation layer in accordance with example embodiments of inventive concepts.

FIGS. 8 to 12 are cross-sectional views illustrating a method of forming an insulating interlayer and a contact plug in accordance with example embodiments of inventive concepts.

FIGS. 13 and 14 are graphs illustrating misalignment degree of silicon oxide layer patterns in accordance with experimental example embodiments of inventive concepts and comparative experimental embodiments.

It should be noted that these figures are intended to illustrate the general characteristics of methods, structure and/or materials utilized in certain example embodiments of inventive concepts and to supplement the written description provided below. These drawings are not, however, to scale and may not precisely reflect the precise structural or performance characteristics of any given embodiment, and should not be interpreted as defining or limiting the range of values or properties encompassed by example embodiments of inventive concepts. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS OF INVENTIVE CONCEPTS

Various example embodiments of inventive concepts will be described more fully hereinafter with reference to the accompanying drawings, in which some example embodiments of inventive concepts are shown. Example embodiments of inventive concepts may, however, be embodied in many different forms and should not be construed as limited to the example embodiments of inventive concepts set forth herein. Rather, these example embodiments of inventive concepts are provided so that this disclosure will be thorough and complete, and will fully convey the scope of example embodiments of inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments of inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments of inventive concepts only and is not intended to be limiting of example embodiments of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of inventive concepts are described herein with reference to cross-sectional illustrations that are schematic illustrations of idealized example embodiments of inventive concepts (and intermediate structures). As such, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of inventive concepts.

Unless otherwise defined, all terms (including technical and scientific terms) used herein have the same meaning as commonly understood by one of ordinary skill in the art to which example embodiments of inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of inventive concepts relate to methods of forming a silicon oxide layer and methods of forming an isolation layer using the same. More particularly, example embodiments of inventive concepts relate to methods of forming a silicon oxide layer having increased alignment characteristics and methods of forming an isolation layer using the same.

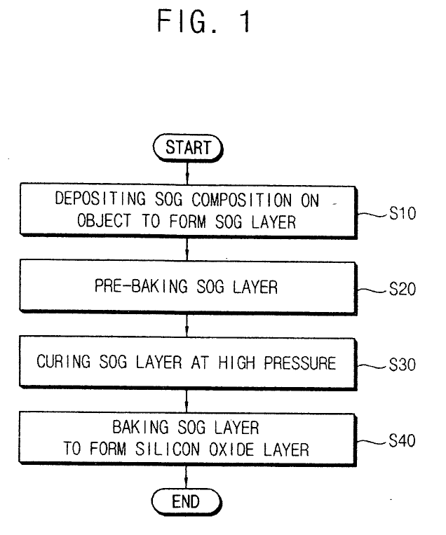

FIG. 1 is a flow chart illustrating a method of forming a silicon oxide layer in accordance with example embodiments of inventive concepts.

Referring to FIG. 1, an SOG composition may be deposited on an object to form an SOG layer (S10).

The object may include a semiconductor substrate (e.g., a silicon substrate, a germanium substrate a silicon-germanium substrate, etc.), a silicon-on-insulator (SOI) substrate, a germanium-on-insulator (GOI) substrate, or a metal oxide single crystalline substrate (e.g., an aluminum oxide (AlOₓ) single crystalline substrate, a strontium titanium oxide (SrTiOₓ) single crystalline substrate, a magnesium oxide (MgOₓ) single crystalline substrate or similar single crystalline substrate).

The object may include a recess. The recess may be formed using patterns on the object. When a plurality of recesses is formed, the recesses may have different widths and/or depths from each other.

The SOG composition may include perhydropolysilazane and a solvent. According to example embodiments of inventive concepts, the SOG composition may include about 15% to about 25% by weight of perhydropolysilazane and the remaining amount of the solvent. Perhydropolysilazane may include Si—N bonds without carbon, Si—H bonds and N—H bonds. Perhydropolysilazane may form a silicon oxide layer by a heat treatment. The silicon oxide layer formed using perhydropolysilazane may have increased gap-fill characteristics. The SOG composition including perhydropolysilazane may have increased flowability, and thus the silicon oxide layer may be more evenly flat.

When the SOG composition includes less than about 15% by weight of perhydropolysilazane, the viscosity of the SOG composition may decrease so that the thickness of the SOG layer may not be easily controlled. When the SOG composition includes more than about 25% by weight of perhydropolysilazane, the viscosity of the SOG composition may increase so that the thickness of the SOG layer may be substantially large and that the uniformity of the SOG layer may decrease.

The perhydropolysilazane included in the SOG composition may have a weight average molecular weight of about 2,000 to about 4,500 and a number average molecular weight of about 500 to about 2,000. The perhydropolysilazane may be represented by following Formula (1).

—(SiH₂NH)ₙ— FORMULA (1)

In Formula (1), n may represent a positive integer from about 85 to about 185. When the weight average molecular weight of the perhydropolysilazane is less than about 2,000, the viscosity of the SOG composition may decrease so that the thickness of the SOG layer may not be easily controlled. When the weight average molecular weight of the perhydropolysilazane is over about 4,500, cracks may be generated in the SOG layer in a subsequent baking process.

When the number average molecular weight of the perhydropolysilazane is less than about 500, cracks may be generated in the SOG layer in a subsequent baking process and/or in a subsequent annealing process. When the number average molecular weight of the perhydropolysilazane is over about 2,000, the uniformity of the SOG layer may be deteriorated.

The SOG composition may include the remaining amount of the solvent. According to example embodiments of inventive concepts, the solvent may include an aliphatic hydrocarbon solvent, an aromatic hydrocarbon solvent, a ketone-based solvent, an ether-based solvent, an acetate-based solvent, an alcohol-based solvent, an amide-based solvent or a similar solvent. For example, the solvent may include at least one of toluene, benzene, xylene, dibutylether, diethyl ether, tetrahydrofuran (THF), propylene glycol methyl ether (PGME), propylene glycol methyl ether acetate (PGMEA) and hexane. These may be used alone or in combination thereof.

The SOG composition may be deposited on the object including the recess to form the SOG layer filling the recess. The SOG layer may be formed by a spin-coating process.

A pre-baking process may be performed on the SOG layer (S20). In the pre-baking process, the solvent may be removed and some of the Si—N bonds or the Si—H bonds in the SOG layer may be transformed into S—O bonds or Si—OH bonds.

According to example embodiments of inventive concepts, the pre-baking process may include a first pre-baking process and a second pre-baking process. According to example embodiments of inventive concepts, the first and second pre-baking processes may be continuous. According to other example embodiments of inventive concepts, the first pre-baking process may be separate from the second pre-baking process. The first pre-baking process may be performed at about 70° C. to about 150° C. to remove some of the solvent included in the SOG layer without applying a thermal stress onto the object. The second pre-baking process may be performed at about 200° C. to about 350° C. to partially transform the Si—N bonds or the Si—H bonds included in the SOG layer into the S—O bonds or the Si—OH bonds. When the pre-baking is performed at a temperature above about 350° C., the transformation of the Si—N bonds or the Si—H bonds into the S—O bonds or the Si—OH bonds may proceed rapidly thereby generating cracks in the SOG layer.

A curing process may be performed on the pre-baked SOG layer under a substantially high pressure (S30).

The curing process may be performed at a pressure of about 1.5 atm to about 100 atm by contacting the SOG layer with one of water, a basic material and an oxidant. In the curing process, the Si—H bonds or the Si—N bonds remaining in the SOG layer after the pre-baking process may be transformed into the Si—OH bonds or the S—O bonds. Therefore, the rapid volume change of the SOG layer due to the rapid change of the chemical structures thereof during the subsequent baking process may be prevented (or reduced), thereby reducing misalignment thereof.

The curing process may be performed at a substantially high pressure above the normal atmospheric pressure. When the curing process is performed at the substantially high pressure, the misalignment may be reduced by about 10% to about 50% when compared to that obtained at the normal atmospheric pressure.

According to example embodiments of inventive concepts, the curing process may be performed at about 1.5 atm to about 100 atm. When the curing process is performed at a pressure lower than 1.5 atm, the alignment characteristics may not be effectively increased when compared to those obtained at the normal pressure. When the curing process is performed at a pressure above about 100 atm, the curing process may generate security (or stability) problems in addition to the difficulty of forming and/or maintaining the substantially high pressure. Accordingly, the curing process according to example embodiments of inventive concepts may be implemented at about 1.5 atm to about 100 atm. The curing process may be performed at about 2 atm to about 15 atm.

The curing process may be performed at a temperature of about 50° C. to about 150° C. When the curing process is performed at a temperature lower than about 50° C., the transformation of the Si—H bonds or the Si—N bonds into the Si—OH bonds or the S—O bonds may not occur. When the curing process is performed at a temperature above about 150° C., the Si—H bonds or the Si—N bonds may be very rapidly transformed into the Si—OH bonds or the S—O bonds to generate cracks in the silicon oxide layer subsequently formed. Accordingly, the curing process may be performed at about 50° C. to about 150° C. The curing process may be performed at about 70° C. to about 130° C.

The curing process may be performed by contacting the pre-baked SOG layer with at least one of water, the basic material and the oxidant. The water, the basic material and the oxidant may provide the pre-baked SOG layer with oxygen atoms so that the Si—H bonds or the Si—N bonds therein may be replaced with the Si—OH bonds or the S—O bonds.

According to example embodiments of inventive concepts, the object including the SOG layer may be immersed into a bath including water, a liquid state of the basic material or a liquid state of the oxidant. Alternatively, water, the liquid basic material or the liquid oxidant may be sprayed onto the SOG layer. According to other example embodiments of inventive concepts, the object including the SOG layer may be positioned in a container. Water vapor, a gas state of the basic material or a gas state of the oxidant may be provided into the container. Alternatively, water, the basic material or the oxidant may be provided into the container and then vaporized therein.

For example, the basic material may include ammonia (NH₃), ammonium hydroxide (NH₄OH), tetra methyl ammonium hydroxide (N(CH₃)₄OH), sodium hydroxide (NaOH), magnesium hydroxide (Mg(OH)₂), calcium hydroxide (Ca(OH)₂), potassium hydroxide (KOH) or a similar basic material. These compounds may be used alone or in combination thereof.

For example, the oxidant may include oxygen (O₂), ozone (O₃), nitrous acid (HNO₂), perchloric acid (HClO₄), chloric acid (HClO₃), chlorous acid (HClO₂), hypochlorous acid (HClO), hydrogen peroxide (H₂O₂), sulfuric acid (H₂SO₄) or a similar oxidant. These compounds may be used alone or in combination thereof.

According to example embodiments of inventive concepts, the basic material or the oxidant along with water may make contact with the SOG layer. The basic material or the oxidant may be dissolved into the water, and an aqueous solution thereof may make contact with the SOG layer. Alternatively, an aqueous solution including the basic material or the oxidant may be vaporized, and a gas vaporized from the aqueous solution may make contact with the SOG layer. Alternatively, water vapor and a gas including the aqueous basic material and/or the aqueous oxidant may be provided onto the SOG layer, and make contact with the SOG layer simultaneously or sequentially.

For example, an aqueous hydrogen peroxide solution including from about 15% to about 20% by weight of hydrogen peroxide, a concentrated sulfuric acid solution including about 98% by weight of sulfuric acid, or an aqueous ammonium hydroxide solution including from about 3% to about 7% by weight of ammonium hydroxide may be used.

According to example embodiments of inventive concepts, the curing process may be implemented within an autoclave. A substantially high-pressure environment may be created in the curing process by means of the autoclave.

According to example embodiments of inventive concepts, after the SOG layer is immersed into a bath including water, the basic material, the oxidant or the aqueous solution including the basic material or the oxidant, the bath may be loaded into the autoclave that is at a substantially high-temperature and a substantially high-pressure.

According to other example embodiments of inventive concepts, water, the basic material or the oxidant, or the aqueous solution including the basic material or the oxidant, may be filled into a lower portion of the autoclave. The object including the SOG layer may be disposed over the water, the basic material or the oxidant, or the aqueous solution so that the object may not contact the above materials. The pressure and the temperature of the autoclave may be set to specific values so that the water, the basic material or the oxidant, or the aqueous solution may be vaporized to contact the SOG layer.

According to still other example embodiments of inventive concepts, the object including the SOG layer may be loaded into the autoclave, and water vapor and a gas including the basic material and/or the oxidant may be provided into the autoclave through an inlet to make contact with the SOG layer.

According to example embodiments of inventive concepts, the curing process may be performed for about 5 seconds to about 30 minutes. When the curing process is performed for less than about 5 seconds, a curing effect may be very small (or incomplete). When the curing process is performed for more than about 30 minutes, the curing effect may not be better (or exhibit the same or less integrity) when compared to that of 30 minutes.

As mentioned above, when the pre-baked SOG layer under a high substantially pressure makes contact with at least one of water, the basic material or the oxidant to be cured, the Si—H bonds or the Si—N bonds of the SOG layer may be gradually transformed into the Si—OH bonds or the S—O bonds. The shrinkage of the SOG layer due to the change of the chemical structures therein may be decreased. Thus, even when the SOG layer is formed on a plurality of recesses having different depths and widths, the shrinkage difference among the parts of the SOG layer on the recesses may not be very large so that misalignment may decrease, or be prevented.

A baking process may be performed on the SOG layer cured under the substantially high pressure, thereby forming the silicon oxide layer on the object (S40).

In the cured SOG layer, the Si—N bonds or the Si—H bonds rarely exist. However, a large number of Si—OH bonds may be present. The cured SOG layer may include silicon oxide having a small molecular weight because of the Si—OH bonds. After performing the baking process, the Si—OH bonds may be removed so that the silicon oxide layer may include a sufficient (or desired) amount of S—O bonds, thereby having a large molecular weight.

The baking process may be performed at about 400° C. to about 1,000° C. When the baking process is performed at a temperature lower than about 400° C., the Si—OH bonds included in the cured SOG layer may not be removed easily. When the baking process is performed at a temperature above about 1,000° C., thermal load may be imposed on the object. When other layers including silicon nitride have been already formed on the object, the layer may be oxidized. The baking process may be performed at a temperature of about 400° C. to about 1,000° C. The baking process may be performed at a temperature of about 450° C. to about 600° C.

According to the above-illustrated method, the rapid shrinkage of the SOG layer including perhydropolysilazane may be minimized. The shrinkage difference among the parts of the SOG layer on the recesses may not be very large so that misalignment may decrease, or be prevented.

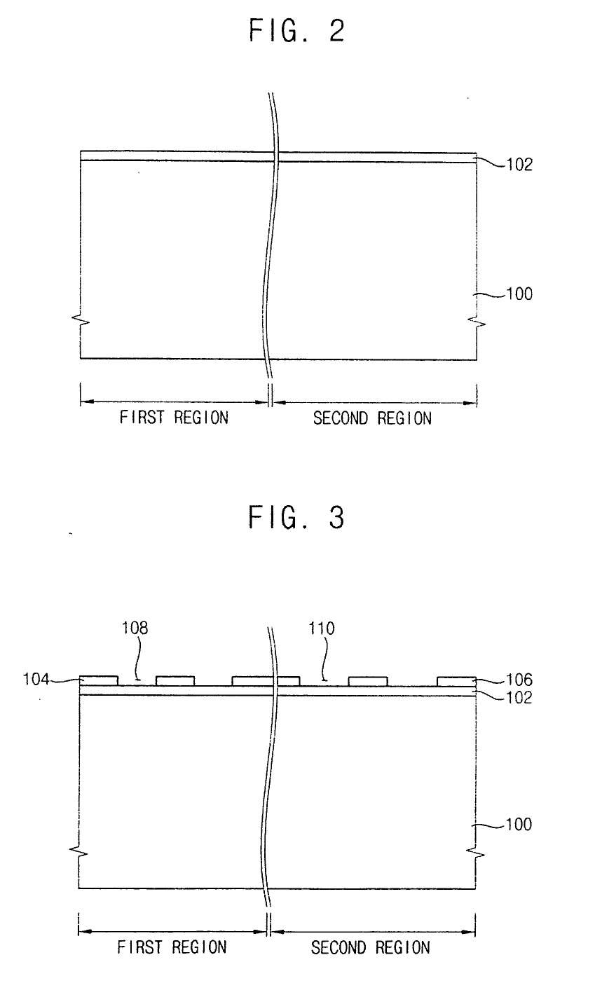

FIGS. 2 to 7 are cross-sectional views illustrating a method of forming an isolation layer in accordance with example embodiments of inventive concepts.

Referring to FIG. 2, a pad oxide layer 102 may be formed on a substrate 100. The substrate 100 may include a semiconductor substrate (e.g., a silicon substrate, a germanium substrate, a silicon-germanium substrate, etc.), an silicon-on-insulator (SOI) substrate, a germanium-on-insulator (GOI) substrate, or a metal oxide single crystalline substrate (e.g., aluminum oxide (AlOₓ) single crystalline substrate, a strontium titanium oxide (SrTiOₓ) single crystalline substrate, a magnesium oxide (MgOₓ) single crystalline substrate or a similar single crystalline substrate).

The substrate 100 may include a first region and a second region. According to example embodiments of inventive concepts, the first region may be a cell region in which memory cells may be formed and the second region may be a peripheral region in which peripheral circuits may be formed.

The pad oxide layer 102 may be formed using silicon oxide. The pad oxide layer 102 may be formed by a thermal oxidation process or a chemical vapor deposition (CVD) process.

Referring to FIG. 3, first patterns 104 and second patterns 106 may be formed on the pad oxide layer 102.

Particularly, a layer may be formed on the pad oxide layer 102. The layer may be partially removed to form the first and second patterns 104 and 106 on the pad oxide layer 102. The first patterns 104 may be formed in the first region of the substrate 100. The first patterns 104 may be spaced apart from each other by a first opening 108 having a first width and exposing a portion of the pad oxide layer 102 in the first region. The second patterns 106 may be formed in the second region of the substrate 100. The second patterns 106 may be spaced apart from each other by a second opening 110 having a second width and exposing a portion of the pad oxide layer 102 in the second region.

For example, the first patterns 104 and the second patterns 106 may be formed using a nitride compound, an oxide compound or a carbide compound. According to example embodiments of inventive concepts, the first patterns 104 and the second patterns 106 may have a single-layered structure. Alternatively, the first and second patterns 104 and 106 may have a multi-layered structure.

Particularly, a thin film (not shown) including the nitride compound may be formed on the pad oxide layer 102. On the thin film, an amorphous carbon layer (not shown) and an anti-reflection layer (not shown) may be successively formed. The amorphous carbon layer and the anti-reflection layer may be formed to prevent deterioration of sidewall profiles of photoresist patterns (not shown) due to diffused reflection during a subsequently implemented photolithography process. On the anti-reflection layer, first photoresist patterns (not shown) spaced apart by the first width and second photoresist patterns (not shown) spaced apart by the second width may be formed. The anti-reflection layer, the amorphous carbon layer and the thin film may be etched using the first and second photoresist patterns as etching masks to form the first patterns 104, the second patterns 106, anti-reflection layer patterns (not shown) and amorphous carbon layer patterns (not shown) on the pad oxide layer 102. The first and second photoresist patterns, the anti-reflection layer patterns and the amorphous carbon layer patterns may be removed.

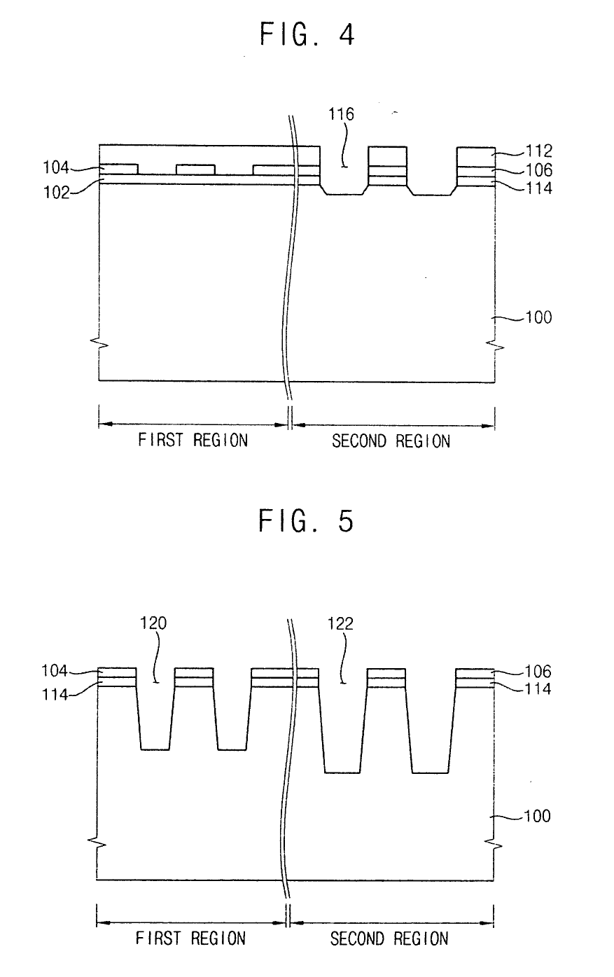

Referring to FIG. 4, third photoresist patterns 112 may be formed on the first patterns 104 and the second patterns 106 to fill the first opening 108. The portion of the pad oxide layer 102 in the second region may be still exposed by the second opening 110.

The exposed portion of the pad oxide layer 102 and a portion of the substrate 100 therebeneath in the second region may be etched using the third photoresist patterns 112 as etching masks to form a pad oxide layer pattern 114 and a recess 116 in the second region. The third photoresist patterns 112 may be removed so that the first and second patterns 104 and 106 and the portion of the pad oxide layer 102 previously exposed by the first opening 108 may be exposed.

Referring to FIG. 5, the exposed portion of the pad oxide layer 102 in the first region, a portion of the substrate 100 therebeneath, and the exposed portion of the substrate 100 by the recess 116 in the second region may be etched using the first patterns 104 and the second patterns 106 as etching masks to form a first trench 120 and a second trench 122.

The first trench 120 may be formed in the first region of the substrate 100. The first trench 120 may have an upper width substantially the same as the first width and a first depth. The first trench 120 may have a lower width smaller than the upper width.

The second trench 122 may be formed in the second region of the substrate 100. The second trench 122 may have an upper width substantially the same as the second width and a second depth. The second trench 122 may have a lower width smaller than the upper width. The second depth of the second trench 122 may be deeper than the first depth of the first trench 120 because the second trench 122 may be formed by etching the recess 116.

According to example embodiments of inventive concepts, the first and second trenches 120 and 122 may be formed by performing a plasma etching process.

Alternatively, the recess 116 may not be formed in the second region before forming the second trench 122 by controlling the second width of the second opening 110. When the second opening 110 has the second width larger than the first width of the first opening 108, the second trench 122 may also have a width larger than that of the first trench 120, thereby the second trench 122 may be formed deeper than the first trench 120 (the second depth deeper than the first depth) in the same etching process even without forming the recess 116 previously.

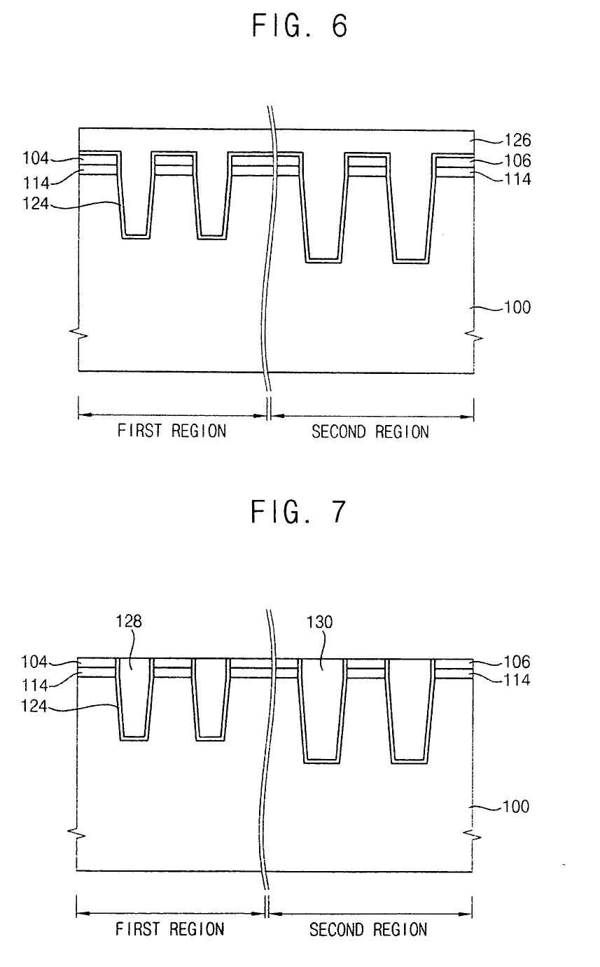

Referring to FIG. 6, a field insulation layer 126 filling the first trench 120 and the second trench 122 may be formed on the substrate 100, the first and second patterns 104 and 106, and the pad oxide layer pattern 114 using the SOG composition including perhydropolysilazane.

According to example embodiments of inventive concepts, a liner 124 may be formed on the substrate 100, the pad oxide layer pattern 114 and the first and second patterns 104 and 106 before forming the field insulation layer 126. The liner 124 may prevent (or reduce) oxidation of the exposed portion of the substrate 100 by the first and second trenches 120 and 122 during formation of the field insulation layer 126.

The field insulation layer 126 may be formed by following processes. An SOG layer filling the first and second trenches 120 and 122 may be formed on the substrate 100 using the SOG composition including perhydropolysilazane. The SOG composition may include about 15% to about 25% by weigh of perhydropolysilazane and the remaining amount of a solvent.

A pre-baking process may be performed on the SOG layer to remove a portion of the solvent included in the SOG layer and to partially transform the Si—N bonds or the Si—H bonds included in the SOG layer into the S—O bonds or the Si—OH bonds.

The pre-baking process may include a first pre-baking process performed at a temperature of about 70° C. to about 150° C. and a second pre-baking process performed at a temperature of about 200° C. to about 350° C.

A curing process at a substantially high pressure may be performed on the pre-baked SOG layer. The curing process may be performed under a pressure of about 1.5 atm to about 100 atm by contacting the SOG layer with at least one of water, a basic material or an oxidant.

Through the curing process performed at the substantially high pressure, a sufficient amount (or a substantial portion) of the Si—H bonds or the Si—N bonds included in the pre-baked SOG layer may be transformed into the Si—OH bonds or the S—O bonds. During a subsequently performed baking at the substantially high temperature, a rapid shrinkage of the SOG layer due to a rapid change of chemical structures thereof may be prevented (or reduced).

The Si—H bonds or the Si—N bonds included in the SOG layer may not be sufficiently transformed into the Si—OH bonds or the S—O bonds if the curing process is not performed, or the SOG layer makes contact with water, the oxidant or the basic material at the normal pressure. In this case, the Si—H bonds or the Si—N bonds may be rapidly transformed into the Si—OH bonds or the S—O bonds during the subsequent baking process, so that the shrinkage of portions of the SOG layer filling the first and second trenches 120 and 122 having different widths and depths may differ from each other. Portions of the substrate 100 adjacent to the first and second trenches 120 and 122 may be under an irregular pressure, and misalignment of the first and second trenches 120 and 122 and further the SOG layer may occur.

When the curing process is performed on the SOG layer filling the first and second trenches 120 and 122 at a substantially high pressure prior to performing the baking process according to example embodiments of inventive concepts, the rapid shrinkage of the SOG layer on the first and second trenches 120 and 122 having different widths and depths may be prevented (reduced), and thus the misalignment may be prevented.

According to example embodiments of inventive concepts, the substrate 100 including the pre-baked SOG layer may be loaded into an autoclave so that the curing process may be performed. For example, the substrate 100 including the pre-baked SOG layer may contact water, the basic material or the oxidant in the autoclave at a pressure of about 2 atm to about 15 atm and a temperature of about 70° C. to about 130° C.

According to example embodiments of inventive concepts, the curing process may be performed by immersing the substrate 100 including the SOG layer into water, a liquid state of the basic material and/or a liquid state of the oxidant, or by spraying the water and/or the liquid onto the substrate 100 including the SOG layer. According to other example embodiments of inventive concepts, the curing process may be performed by contacting the SOG layer with water vapor and a gas state of the basic material and/or a gas state of the oxidant.

The baking process may be performed on the cured SOG layer at a substantially high pressure and at a temperature of about 400° C. to about 1,000° C. to form the field insulation layer 126 including silicon oxide. Through the baking, the Si—OH bonds included in the cured SOG layer may be removed, and the field insulation layer 126 may include a sufficient amount of S—O bonds. The field insulation layer 126 may include silicon oxide having a substantially large molecular weight.

Referring to FIG. 7, an upper portion of the field insulation layer 126 may be planarized until the first pattern 104 and the second pattern 106 are exposed to form a first field insulation layer pattern 128 and a second field insulation layer pattern 130, which fill the first trench 120 and the second trench 122, respectively. The first and second field insulation layer patterns 128 and 130 may serve (or function) as isolation layers, which have different widths and depths in the first and second regions, respectively.

According to example embodiments of inventive concepts, the upper portion of the field insulation layer 126 may be planarized by a chemical mechanical polishing (CMP) process and/or an etch-back process.

When the isolation layer filling the first and second trenches 120 and 122 having different widths and depths is formed by the above-mentioned method, the rapid shrinkage of the SOG layer filling the trenches 120 and 122 may be prevented (or reduced). The substrate 100 may be less damaged (or susceptible to less damage) due to the shrinkage of the SOG layer when the SOG layer is transformed into the isolation layer, and the isolation layer may be formed at a desired position.

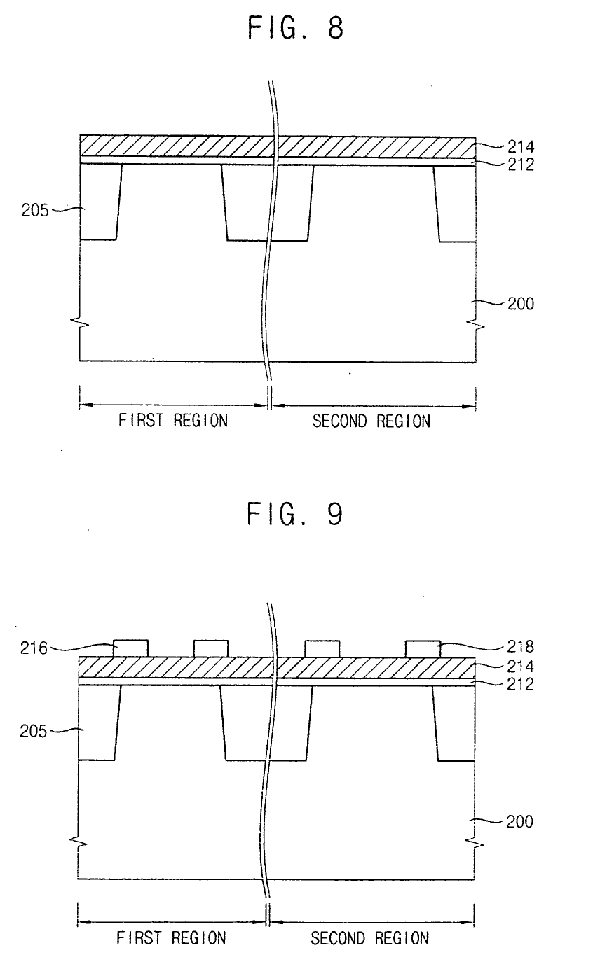

FIGS. 8 to 12 are cross-sectional views illustrating a method of forming an insulating interlayer and a contact plug in accordance with example embodiments of inventive concepts.

Referring to FIG. 8, a gate insulation layer 212 and a first conductive layer 214 may be formed on a substrate 200 including an isolation layer 205.

The substrate 200 may be divided into a first region and a second region. The first region may be a cell region in which memory cells may be formed and the second region may be a peripheral region in which peripheral circuits may be formed.

The isolation layer 205 may be formed on the substrate 200 divided into the first region and the second region. The isolation layer 205 may be formed by performing processes substantially the same as, or similar to, those illustrated with reference to FIGS. 2 to 7.

The gate insulation layer 212 may be formed using silicon oxide or silicon oxynitride. The gate insulation layer 212 may be formed by a thermal oxidation process or a CVD process.

The first conductive layer 214 may be formed on the gate insulation layer 212. The first conductive layer 214 may be formed using a metal or polysilicon doped with impurities. For example, the metal may include titanium (Ti), tungsten (W), tantalum (Ta), ruthenium (Ru) and combinations thereof.

According to example embodiments of inventive concepts, the first conductive layer 214 may be formed by a CVD process, a physical vapor deposition (PVD) process, an atomic layer deposition (ALD) process or a similar process.

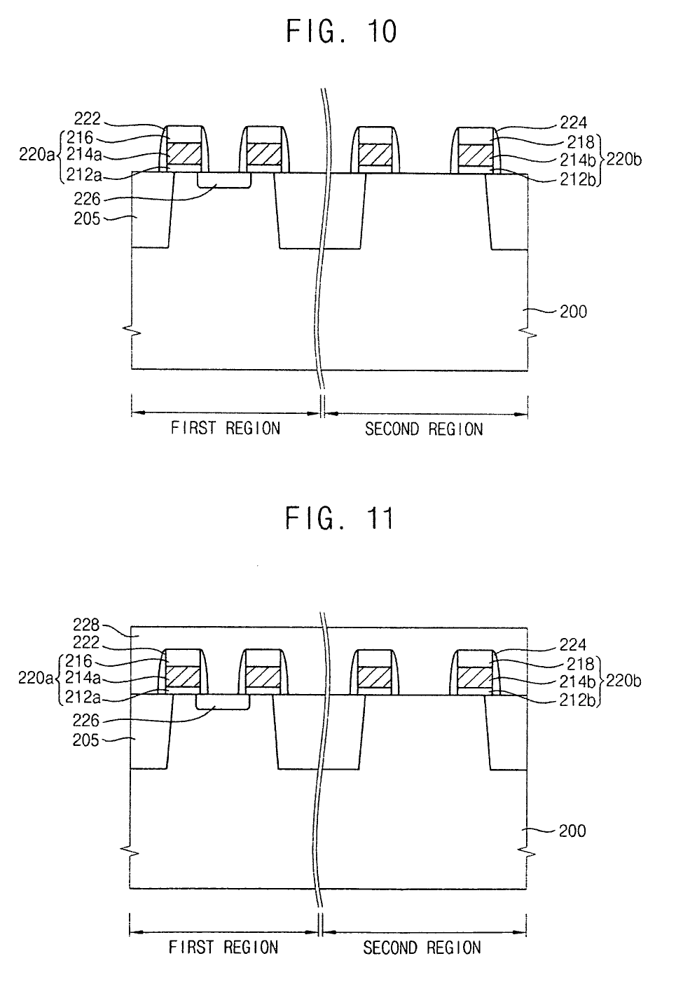

Referring to FIG. 9, third patterns 216 and fourth patterns 218 may be formed on the first conductive layer 214.

The third patterns 216 may be formed in the first region of the substrate 100 and may be spaced apart from each other by a third width. The fourth patterns 218 may be formed in the second region of the substrate 100 and may be spaced apart from each other by a fourth width larger than the third width.

Third and fourth patterns 216 and 218 may be formed by performing processes substantially the same as, or similar to, those for forming the first patterns 104 and the second patterns 106 with reference to FIG. 3.

Referring to FIG. 10, first gate structures 220a and second gate structures 220b may be formed in the first region and the second region, respectively, using the third and fourth patterns 216 and 218 as etching masks.

The first gate structures 220a and the second gate structures 220b may be formed by patterning the gate insulation layer 212 and the first conductive layer 214 by an etching process using the third and fourth patterns 216 and 218 as the etching masks. The first gate structures 220a each of which includes a first gate insulation pattern 212a, a first gate conductive pattern 214a and the third pattern 216 may be formed in the first region of the substrate 200. The second gate structures 220b each of which includes a second gate pattern 212b, a second gate conductive pattern 214b and the fourth pattern 218 may be formed in the second region of the substrate 200.

According to example embodiments of inventive concepts, the interval between the first gate structures 220a in the first region may be substantially the same as the interval between the third patterns 216, that is, the third width. The interval between the second gate structures 220b in the second region may be substantially the same with the interval between the fourth patterns 218, that is, the fourth width. The interval between the second gate structures 220b may be substantially wider than the interval between the first gate structures 220a.

A spacer layer covering the first gate structures 220a and the second gate structures 220b may be formed on the substrate 200. The spacer layer may be etched to form first spacers 222 on sidewalls of the first gate structures 220a and second spacers 224 on sidewalls of the second gate structures 220b.

An ion implantation process may be performed onto the first region of the substrate 200 using the first gate structures 220a and the first spacers 222 as ion implantation masks to form an impurity region 226 at an upper portion of the substrate 200.

Referring to FIG. 11, the SOG composition may be deposited on the substrate 200 to form an insulating interlayer 228 to cover the first gate structures 220a, the first spacers 222, the second gate structures 220b and the second spacers 224. The insulating interlayer 228 may be formed by following processes.

An SOG composition including perhydropolysilazane may be deposited on the substrate 200 to form an SOG layer. The SOG composition may include about 15% to about 25% by weight of perhydropolysilazane and the remaining amount of a solvent.

A pre-baking process may be performed on the SOG layer to remove a portion of the solvent included in the SOG layer and to partially transform the Si—N bonds or the Si—H bonds included in the SOG layer into the S—O bonds or the Si—OH bonds. The pre-baking process may include a first pre-baking process performed at a temperature of about 70° C. to about 150° C. and a second pre-baking process performed at a temperature of about 200° C. to about 350° C.

A curing process at a substantially high pressure may be performed on the pre-baked SOG layer. The curing process may be performed under a pressure of about 1.5 atm to about 100 atm by contacting the SOG layer with at least one of water, a basic material or an oxidant.

During the curing process performed at the substantially high pressure, a sufficient amount of the Si—H bonds or the Si—N bonds included in the pre-baked SOG layer may be transformed into the Si—OH bonds or the S—O bonds. During a subsequently performed baking at the substantially high temperature, a rapid shrinkage of the SOG layer due to a rapid change of chemical structures thereof may be prevented (or reduced).

The Si—H bonds or the Si—N bonds included in the SOG layer may not be sufficiently transformed into the Si—OH bonds or the S—O bonds if the curing process is not performed, or if the SOG layer makes contact with water, the oxidant or the basic material at the normal pressure. In this case, the Si—H bonds or the Si—N bonds may be rapidly transformed into the Si—OH bonds or the S—O bonds during the subsequent baking process, so that the shrinkage of portions of the SOG layer filling gaps between the first gate structures 220a and gaps between the second gate structures 220b may differ from each other. Portions of the substrate 200 adjacent to the gaps may be under an irregular pressure, and misalignment of the first and second gate structures 220a and 220b and further the SOG layer may occur.

When the curing process is performed on the SOG layer at a substantially high pressure prior to performing the baking process according to example embodiments of inventive concepts, the rapid shrinkage of the SOG layer filling the gaps may be prevented (or reduced), thereby misalignment may be prevented.

According to example embodiments of inventive concepts, the substrate 200 including the pre-baked SOG layer may be loaded into an autoclave so that the curing process may be performed. For example, the substrate 200 including the pre-baked SOG layer may make contact with water, the basic material or the oxidant in the autoclave at a pressure of about 2 atm to about 15 atm and a temperature of about 70° C. to about 130° C.

According to example embodiments of inventive concepts, the curing process may be performed by immersing the substrate 200 including the SOG layer into water, a liquid state of the basic material and/or a liquid state of the oxidant, or by spraying the water and/or the liquid onto the substrate 200 including the SOG layer. According to other example embodiments of inventive concepts, the curing process may be performed by contacting the SOG layer with water vapor, a gas state of the basic material and/or a gas state of the oxidant.

The baking process may be performed on the cured SOG layer at a substantially high pressure and at a temperature of about 400° C. to about 1,000° C. to form the insulating interlayer 228 including silicon oxide. Through the baking, the Si—OH bonds included in the cured SOG layer may be removed, and the insulating interlayer 228 may include a sufficient amount of S—O bonds. The insulating interlayer 228 may include silicon oxide having a substantially large molecular weight.

According to example embodiments of inventive concepts, a planarization process may be performed on the insulating interlayer 228. The planarization process may be performed by a CMP process and/or an etch-back process.

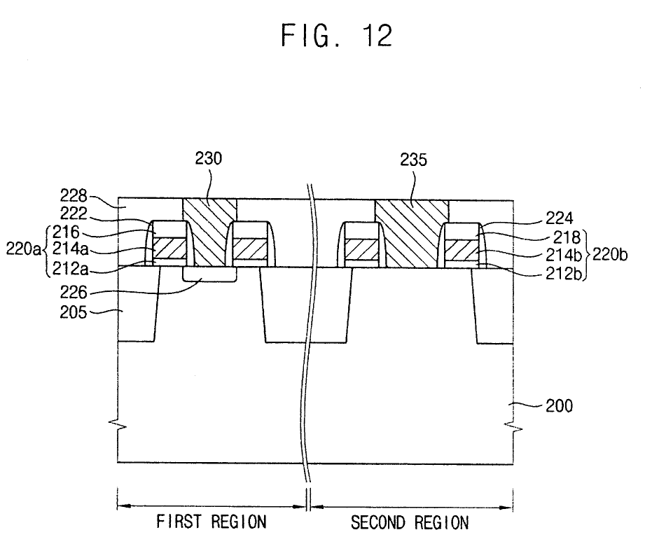

Referring to FIG. 12, contact plugs 230 and 235 may be formed through the insulating interlayer 228.

The contact plugs 230 and 235 may be formed by etching the insulating interlayer 228 to form a first contact hole (not shown) exposing the impurity region in the first region and a second contact hole (not shown) exposing a portion of the substrate 200 in the second region.

A second conductive layer may be formed on the insulating interlayer 228 to fill the first and second contact holes. The second conductive layer may be formed using a metal (e.g., titanium (Ti), tungsten (W), tantalum (Ta), ruthenium (Ru) and combinations thereof) by a CVP process, a PVD process, an ALD process, etc.

An upper portion of the second conductive layer may be planarized until the insulating interlayer 228 may be exposed to form the first contact plug 230 contacting the impurity region 226 and the second contact plug 235 of the substrate 200.

When the insulating interlayer 228 is formed by the above-mentioned method, the rapid shrinkage of the SOG layer filling the gaps may be prevented (or reduced). The substrate 200 may be less damaged (or susceptible to less damage) due to the shrinkage of the SOG layer when the SOG layer is transformed into the insulating interlayer 228, and the misalignment of the insulating interlayer 228 may be prevented (or reduced).

Hereinafter, effects on the misalignment of the silicon oxide layer formed by the method according to example embodiments of inventive concepts will be evaluated.

### EXAMPLE 1

First patterns spaced apart from each other by about 500 Å were provided in a first region of a substrate, and second patterns spaced apart from each other by about 1,000 Å were provided in a second region of a substrate. The substrate was etched using the first patterns and the second patterns as etching masks to form a first trench having a depth of about 2,000 Å in the first region and a second trench having a depth of about 5,000 Å in the second region of the substrate. An SOG layer burying the first and second trenches was formed on the substrate using an SOG composition including about 20% by weight of perhydropolysilazane.

A first pre-baking process at about 120° C. and a second pre-baking process at about 300° C. were performed on the SOG layer. A curing process was performed on the substrate including the pre-baked SOG layer. The curing process was performed after disposing the substrate in an autoclave of which pressure was set to about 2 atm and of which temperature was set to about 120° C. by injecting gas state ozone for about 10 minutes.

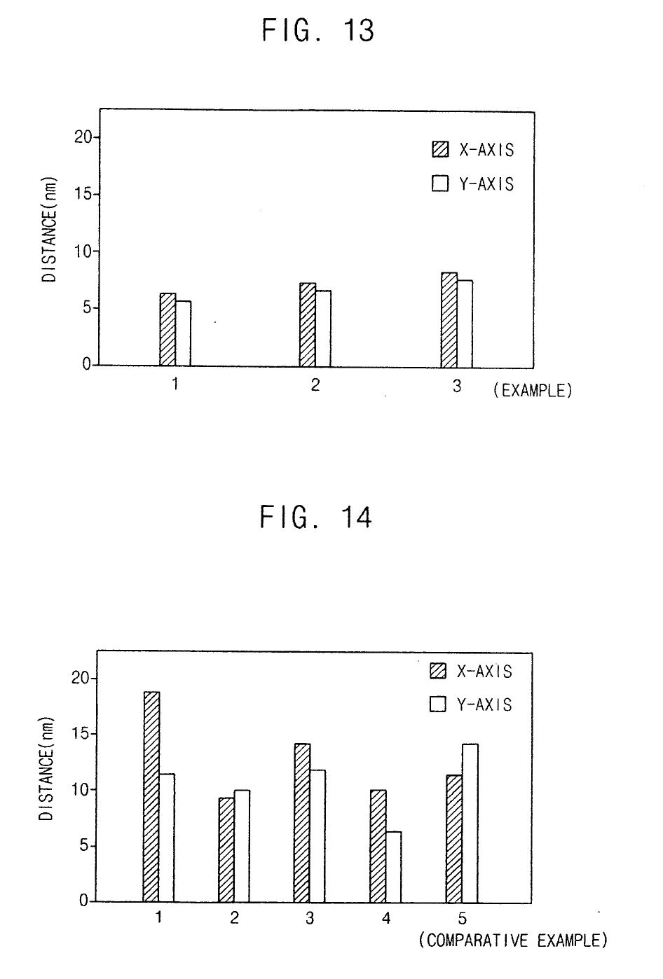

A baking process was performed at about 800° C. on the SOG layer to form a silicon oxide layer on the substrate. The silicon oxide layer was planarized to form a silicon oxide layer pattern burying the first and second trenches on the substrate. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 13.

### EXAMPLE 2

A silicon oxide layer pattern burying a first trench and a second trench on a substrate was formed by performing substantially the same procedure described in Example 1 except that the curing process was performed by setting the temperature of the autoclave to about 105° C. and contacting the pre-baked SOG layer with deionized water instead of ozone. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 13.

### EXAMPLE 3

A silicon oxide layer pattern burying a first trench and a second trench on a substrate was formed by performing substantially the same procedure described in Example 1 except that the curing process was performed by setting the temperature of the autoclave to about 105° C. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 13.

### COMPARATIVE EXAMPLE 1

A silicon oxide layer pattern burying a first trench and a second trench on a substrate was formed by performing substantially the same procedure described in Example 1 except that the curing process was not performed. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 14.

### COMPARATIVE EXAMPLE 2

A silicon oxide layer pattern burying a first trench and a second trench on a substrate was formed by performing substantially the same procedure described in Example 1 except that the curing process was performed by setting the pressure and the temperature of the autoclave to about 1 atm and to about 110° C. and by injecting deionized water into the autoclave. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 14.

### COMPARATIVE EXAMPLE 3

A silicon oxide layer pattern burying a first trench and a second trench on a substrate was formed by performing substantially the same procedure described in Example 1 except that the curing process was performed by setting the pressure and the temperature of the autoclave to about 1 atm and to about 70° C. and by injecting deionized water into the autoclave. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 14.

### COMPARATIVE EXAMPLE 4

A silicon oxide layer pattern burying a first trench and a second trench on a substrate was formed by performing substantially the same procedure described in Example 1 except that the curing process was performed by setting the pressure and the temperature of the autoclave to about 1 atm and to about 110° C. and by injecting about 5% by weight of an aqueous ammonium hydroxide (NH₄OH) solution into the autoclave. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 14.

### COMPARATIVE EXAMPLE 5

A silicon oxide layer pattern burying a first trench and a second trench on a substrate was formed by performing substantially the same procedure described in Example 1 except that the curing process was performed by setting the pressure and the temperature of the autoclave to about 1 atm and to about 70° C. and by injecting about 5% by weight of an aqueous ammonium hydroxide (NH₄OH) solution into the autoclave. The difference in distance (nm), along the x-axis and y-axis of the substrate, between the position of the silicon oxide layer patterns burying the first and second trenches and the position of the first and second patterns on the substrate was measured. Mean values of the measured values are illustrated in FIG. 14.

The process condition of the curing process according to Examples 1 to 3 and Comparative Examples 2 to 5 is illustrated in the following Table 1.

TABLE 1

| | PRESSURE | TEMPERATURE | |
|---|---|---|---|
| | (atm) | (° C.) | MATERIAL |
| Example 1 | 2 | 120 | Ozone vapor |
| Example 2 | 2 | 105 | Deionized water |
| Example 3 | 2 | 105 | Ozone vapor |
| Comparative | 1 | 110 | Deionized water |
| Example 2 | | | |
| Comparative | 1 | 70 | Deionized water |
| Example 3 | | | |
| Comparative | 1 | 110 | Aqueous ammonium |
| Example 4 | | | hydroxide solution |
| Comparative | 1 | 70 | Aqueous ammonium |
| Example 5 | | | hydroxide solution |

FIGS. 13 and 14 are graphs illustrating misalignment degree of silicon oxide layer patterns in accordance with the example experimental embodiments of inventive concepts and the comparative experimental embodiments.

Referring to FIGS. 13 and 14, the silicon oxide layer patterns formed after performing the curing process at the pressure of about 2 atm according to Examples 1 to 3 were obtained at a deviated position by about 5 nm from the position of the first and second patterns on the substrate. The silicon oxide layer patterns formed without performing the curing process according to Comparative Example 1 were obtained at a deviated position by about 20 nm from the position of the first and second patterns on the substrate. The silicon oxide layer patterns formed after performing the curing process at the pressure of about 1 atm according to Comparative Examples 2 to 5 were obtained at a deviated position by from about 10 nm to about 15 nm from the position of the first and second patterns on the substrate. As confirmed from Examples 1-3 and Comparative Examples 1-5, the generation of the misalignment of the silicon oxide layer patterns may be prevented (or reduced) when the SOG layer was brought into contact with the water, the basic material or the oxidant at the substantially high pressure.

According to the example embodiments of inventive concepts of forming the silicon oxide layer, a rapid shrinkage of the SOG layer during performing a baking process at a substantially high temperature may be prevented (or reduced) because of a curing process performed at a substantially high pressure. Damage onto a substrate due to the shrinkage of the SOG layer may be prevented (or reduced) and the generation of the misalignment during forming the isolation layer may be prevented (or reduced).

The foregoing is illustrative of example embodiments of inventive concepts and is not to be construed as limiting thereof. Although a few example embodiments of inventive concepts have been described, those skilled in the art will readily appreciate that many modifications are possible in the example embodiments of inventive concepts without materially departing from the novel teachings and advantages of example embodiments of inventive concepts. Accordingly, all such modifications are intended to be included within the scope of example embodiments of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments of inventive concepts and is not to be construed as limited to the specific example embodiments of inventive concepts disclosed, and that modifications to the disclosed example embodiments of inventive concepts, as well as other example embodiments of inventive concepts, are intended to be included within the scope of the appended claims.

What is claimed is:

1. A method of forming a silicon oxide layer, comprising:
forming a spin-on-glass (SOG) layer using an SOG composition on an object;
pre-baking the SOG layer;
curing the pre-baked SOG layer under a pressure of about 1.5-atm to about 100-atm by contacting the pre-baked SOG layer with at least one selected from the group consisting of water, a basic material and an oxidant; and
baking the cured SOG layer.

2. The method of claim 1, wherein curing the pre-baked SOG layer is performed in an autoclave.

3. The method of claim 1, wherein the basic material includes at least one selected from the group consisting of ammonia (NH₃), ammonium hydroxide (NH₄OH), tetra methyl ammonium hydroxide (N(CH₃)₄OH), sodium hydroxide (NaOH), magnesium hydroxide (Mg(OH)₂), calcium hydroxide (Ca(OH)₂), potassium hydroxide (KOH) and combinations thereof.

4. The method of claim 1, wherein the oxidant includes at least one selected from the group consisting of oxygen (O₂), ozone (O₃), nitrous acid (HNO₂), perchloric acid (HClO₄), chloric acid (HClO₃), chlorous acid (HClO₂), hypochlorous acid (HClO), hydrogen peroxide (H₂O₂), sulfuric acid (H₂SO₄) and combinations thereof.

5. The method of claim 1, wherein the SOG composition includes from about 5% to about 25% by weight of perhydropolysilazane and a remaining amount of solvent.

6. The method of claim 5, wherein the perhydropolysilazane has a weight average molecular weight of about 2,000 to about 4,500 and a number average molecular weight of about 500 to about 2,000.

7. The method of claim 5, wherein the solvent includes at least one selected from the group consisting of toluene, benzene, xylene, dibutylether, diethyl ether, tetrahydrofuran (THF), propylene glycol methyl ether (PGME), propylene glycol methyl ether acetate (PGMEA), hexane and combinations thereof.

8. The method of claim 1, wherein the object has a trench thereon, and forming the SOG layer includes filling the trench.

9. The method of claim 1, wherein the object has a first trench having a first width and a second trench having a second width different from the first width.

10. The method of claim 1, wherein curing the pre-baked SOG layer is performed by either immersing the SOG layer into water, a liquid state of the basic material, a liquid state of the oxidant or a liquid state of a combination thereof, or by spraying the water, the liquid state of the basic material, the liquid state of the oxidant or the liquid state of the combination thereof onto the SOG layer.

11. The method of claim 1, wherein curing the pre-baked SOG layer is performed by contacting the SOG layer with water vapor, a gas state of the basic material, a gas state of the oxidant or a gas state of a combination thereof.

12. The method of claim 1, wherein curing the pre-baked SOG layer is performed by contacting the SOG layer with an aqueous solution of the basic material or an aqueous solution of the oxidant.

13. The method of claim 1, wherein curing the pre-baked SOG layer is performed at a temperature of about 50° C. to about 150° C.

14. The method of claim 1, wherein curing the pre-baked SOG layer is performed for about 5-seconds to about 30-minutes.

15. The method of claim 1, wherein curing the pre-baked SOG layer is performed at a temperature of about 70° C. to about 130° C. under a pressure of about 2-atm to about 15-atm.

16. The method of claim 1, wherein pre-baking the SOG layer includes:
first pre-baking the SOG layer at a temperature of about 70° C. to about 150° C.; and
secondly pre-baking the first pre-baked SOG layer at a temperature of about 200° C. to about 350° C.

17. The method of claim 1, wherein baking the cured SOG layer is performed at a temperature of about 400° C. to about 1,000° C.

18. A method of forming an isolation layer, comprising:
forming a substrate having a first trench and a second trench, the first trench having a first width and a first depth, and the second trench having a second width and a second depth;
forming the silicon oxide layer according to claim 1 in the first and second trenches by filling the SOG layer in the first and second trenches, wherein baking the SOG layer transforms the cured SOG layer into the silicon oxide layer, the silicon oxide layer being the isolation layer.

19. The method of claim 18, wherein the substrate includes a cell region and a peripheral region, and wherein the first trench is formed in the cell region and the second trench is formed in the peripheral region.

20. The method of claim 18, wherein the first width and the second width are different from each other.
